(19) United States
(12) Patent Application Publication
(10) Pub. No.: US 2006/0051506 A1
(43) Pub. Date: Mar. 9, 2006

(54) Nitridation of high-k dielectrics

(76) Inventors: Yoshihide Senzaki, Austin, TX (US); Craig Bercaw, Boulder Creek, CA (US); Robert Hood Chatham III, Scotts Valley, CA (US); Randall Higuchi, Mountain View, CA (US); Eugene S. Lopata, Scotts Valley, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/002,365

(22) Filed: Dec. 1, 2004

Related U.S. Application Data
(63) Continuation of application No. 10/702,794, filed on Nov. 5, 2003, now abandoned.
(60) Provisional application No. 60/424,891, filed on Nov. 8, 2002.

(51) Int. Cl. C23C 16/00

(52) U.S. Cl. 427/248.1

(57) ABSTRACT

A method of making high-k dielectrics is provided. The method comprises providing a substrate having a high-k dielectric layer deposited thereon in a process chamber and introducing a nitrogen containing gas into the process chamber to incorporate nitrogen into the high-k dielectric layer. In one embodiment, the nitrogen containing gas is a nitrogen plasma gas from a source disposed outside the process chamber. The nitrogen plasma gas is introduced into the process chamber at a flow rate from 0 to about 5000 sccm over a time period of about 20 to 1800 seconds. In another embodiment, the process chamber is maintained at a pressure of about 1 to 100 Torr, and at a wafer temperature in the range of about 200° C.-700° C. The high-k dielectric film pre-deposited on the substrate can be formed by atomic layer deposition, chemical vapor deposition (CVD), physical vapor deposition (PVD), jet vapor deposition (JVD), aerosol pyrolysis, and spin-coating.

### CROSS-REFERENCES TO RELATED APPLICATIONS

This application claims the benefit of and priority to U.S. Provisional Patent Application No. 60/424,891 filed Nov. 8, 2002, the disclosure of which is hereby incorporated by reference.

### FIELD OF THE INVENTION

The present invention relates generally to the field of semiconductors. More specifically, the present invention relates to nitridation of high-k dielectrics for manufacturing semiconductor devices.

### BACKGROUND OF THE INVENTION

As the scale of future devices aggressively reduces, the use of alternative gate dielectrics to the conventional silicon oxide (SiO₂) are actively sought. Hafnium-based dielectrics have been considered as promising candidates due to their high dielectric constant (k is about 20) and thermal stability in contact with silicon substrates. One problem of prior art hafnium-based dielectrics is that undesirable interfacial silicon oxides (SiO_{X}) are formed between the dielectrics and substrates during process integration of high-k gate stacks in the post-deposition thermal treatment.

Nitrogen containing hafnium-based high-k dielectrics having structures of Hf—O—N and Hf—Si—O—N have been reported recently. These nitrogen containing hafnium-based dielectrics have better electrical properties and thermal stability than non-nitrogen containing counterparts such as hafnium-based dielectrics having structure of HfO₂ and Hf—Si—O. However, fabrication of nitrogen containing hafnium-based dielectrics is very difficult. Prior art methods typically require a system of high vacuum and process temperature. Accordingly, further development in fabrication of high-k dielectrics is needed.

### SUMMARY OF THE INVENTION

A method of making high-k dielectrics is provided. In general, the method comprises providing a substrate having a high-k dielectric layer deposited thereon in a process chamber and introducing a nitrogen containing gas into the process chamber to incorporate nitrogen into the high-k dielectric layer. In one embodiment, the nitrogen containing gas is a nitrogen plasma gas from a source outside the process chamber. The nitrogen plasma gas is introduced into the process chamber substantially linearly from 0 to about 5000 sccm over a time period of about 20 to 1800 seconds. In another embodiment, the process chamber is maintained at a pressure of about 1 to 100 Torr, and at a wafer temperature in the range of about 200° C.-700° C. The high-k dielectric film pre-deposited on the substrate can be formed by atomic layer deposition, chemical vapor deposition (CVD), physical vapor deposition (PVD), jet vapor deposition (JVD), aerosol pyrolysis, and spin-coating.

In one embodiment, the substrate having a high-k dielectric film deposited thereon is loaded in a rapid thermal process chamber. A nitrogen containing gas is introduced into the rapid thermal process chamber to incorporate nitrogen into the high-k dielectric film during thermal treatment. The nitrogen containing gas comprises nitrogen, ammonia, mixtures of nitrogen and ammonia, or optionally an inert gas.

In another embodiment, a high-k dielectric film is deposited on a substrate in a first chamber by atomic layer deposition comprising alternatively reacting the surface of the substrate with two precursor gases. Then the substrate having the high-k dielectric film deposited thereon is transferred into a second process chamber. A nitrogen plasma gas is introduced into the second process chamber to incorporate nitrogen into the high-k dielectric film.

### BRIEF DESCRIPTION OF THE DRAWINGS

The present invention will be more clearly understood upon reading the detailed description of the invention and the accompanied drawings, in which:

FIG. 1 is a schematic view of a reaction system which can be used for nitridation of high-k dielectrics according to one embodiment of the present invention;

FIG. 2 is a SIMS plot showing the depth profile of a hafnium oxide (HfO2) film treated by a nitrogen plasma gas according to one embodiment of the invention;

FIG. 3 is a SIMS plot showing the depth profile of a bare silicon wafer treated by a nitrogen plasma according to another embodiment of the present invention.

FIG. 4 is a schematic view of an ALD chamber that can be used for nitridation of high-k dielectrics according to one embodiment of the present invention.

FIG. 5 is a SIMS plot showing the depth profile of an HfSiOx film treated by thermal nitridation according to one embodiment of the present invention.

### DETAILED DESCRIPTION OF THE INVENTION

The present invention provides a method of nitridizing high-k dielectrics using a nitrogen containing gas. In general, the method comprises providing a substrate having a high-k dielectric layer deposited thereon in a process chamber and introducing a nitrogen containing gas into the process chamber to incorporate nitrogen into the high-k dielectric layer.

The high-k dielectrics initially deposited on a substrate can be metal oxides or metal silicates. Examples of metal oxide high-k dielectrics include hafnium oxide (HfO₂). Examples of metal silicate high-k dielectrics include hafnium silicate (Hf—Si—O). Metal oxides and silicates can be deposited on a silicon substrate by any deposition methods such as but not limited to chemical vapor deposition (CVD), atomic layer deposition (ALD), physical vapor deposition (PVD), jet vapor deposition (JVD), aerosol pyrolysis, and spin-coating.

In one embodiment, atomic layer deposition (ALD) is used to deposit a high-k dielectric layer on a substrate. ALD can be performed at comparatively lower temperatures which are suitable for suppressing formation of undesirable interfacial silicon oxides. ALD has relatively high precursor utilization efficiency, and can produce substantially conformal thin film layers. More advantageously, ALD techniques can control the film thickness on an atomic level, and can be used to “nano-engineer” complex thin films. In an ALD process cycle, each reactant gas is introduced independently into a reaction chamber, so that no gas phase intermixing occurs. A monolayer of a first reactant is physi- or chemisorbed onto the substrate surface. Excess first reactant is evacuated from the reaction chamber preferably with the aid of an inert purge gas. A second reactant is then introduced to the reaction chamber and reacts with the first reactant to form a monolayer of the desired thin film via a self-limiting surface reaction. The self-limiting reaction stops once the initially adsorbed first reactant fully reacts with the second reactant. Excess second reactant is evacuated, preferably with the aid of an inert purge gas. A desired film thickness is obtained by repeating the deposition cycle as necessary. The film thickness can be controlled to atomic layer accuracy by simply counting the number of deposition cycles. For example, to deposit a metal oxide high-k dielectric film on a substrate, a metal precursor and an oxygen containing gas can be independently introduced into an atomic layer deposition chamber to alternatively react the surface of the substrate.

The nitrogen containing gas used in the present invention includes nitrogen, ammonia, or mixtures of nitrogen and ammonia. In one embodiment, the nitrogen containing gas includes an inert gas such as but not limited to argon and helium. In another embodiment, the nitrogen containing gas comprises a nitrogen plasma. The nitrogen plasma gas can be from a commercially available plasma source or generated from a plasma generator disposed outside the process chamber. In the embodiment where a plasma generator is used, argon gas can be first introduced to the plasma generator to ignite a plasma Once a plasma is generated, a nitrogen gas is introduced into the generator to generate nitrogen plasma.

The nitrogen containing gas is introduced into a process chamber at a suitable flow rate. In one embodiment, the flow rate of nitrogen containing gas increases substantially linearly from 0 to 5000 sccm over a time period of about 20 to 1800 seconds.

The process chamber in which nitridation of high-k dielectrics is performed is maintained at a pressure in the range of about 1 to 100 Torr and at a wafer temperature in the range of about 200 to 700° C. In one embodiment, the pressure of the process chamber is maintained at about 5 Torr. In another embodiment, the process chamber is maintained at a wafer temperature in the range of about 300 to 600° C.

In one embodiment, the substrate on which a high-k dielectric film deposited is first loaded in a loadlock chamber prior to being transferred into a process chamber for nitridation. Purging gases such as nitrogen are introduced into the loadlock chamber to remove any residual reactant gases such as oxygen used in a previous deposition step.

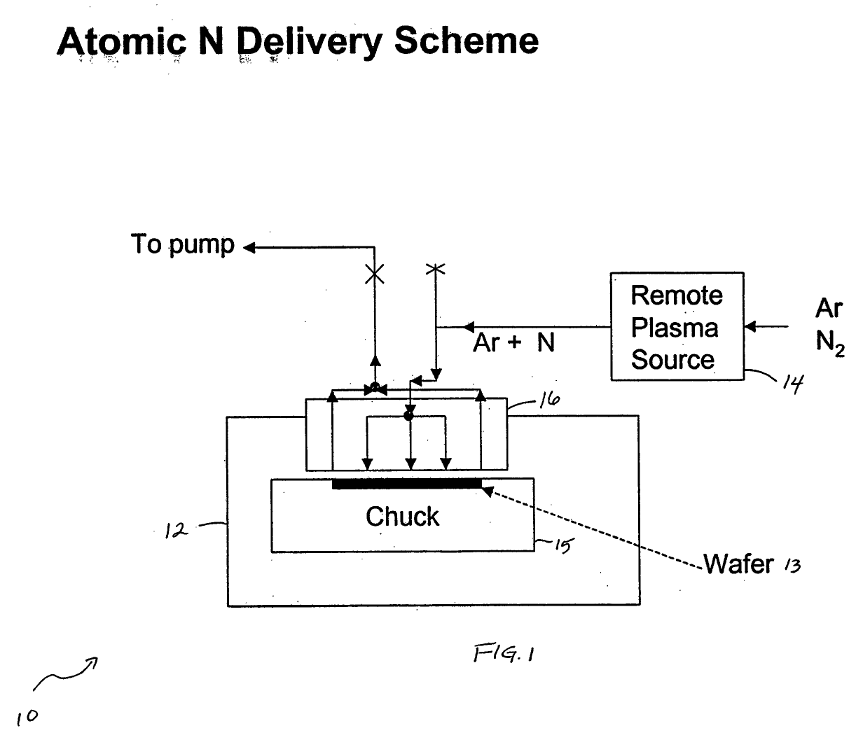

FIG. 1 is a schematic view of a reaction system which can be used to perform the method of the present invention. FIG. 1 is provided for illustrative purpose and is not intended to limit the present invention in any way. For example, the nitridation process of the invention can be performed in a rapid thermal process chamber as described in U.S. Pat. Nos. 6,300,600, 6,462,310, and 6,492,621, the disclosures of which are hereby incorporated by reference. Alternatively, the nitridation process of the invention can be performed in an atomic layer deposition chamber as described in U.S. patent application Ser. No. ______ filed Oct. 15, 2003 (Attorney Docket A-71731), the disclosure of which is hereby incorporated by reference.

Returning to FIG. 1, in this embodiment, the system 12 comprises a process chamber 10 where nitridation is carried out. Wafer 13 is supported on a chuck support 15. A nitrogen plasma source 14 is provided typically outside chamber 12 to supply a nitrogen plasma gas into the chamber. The plasma source 14 can be a plasma generator which dissociates molecular nitrogen to form atomic nitrogen. The term “remote plasma” is used herein to describe a plasma source disposed outside the process chamber. One example of such plasma generator is ASTRON plasma generator available from MKS Instruments in Andover, Mass. One example of the reaction system is APNext Deposition system, available from Aviza Technology, Inc. in Scotts Valley, Calif.

Gases are conveyed to the process chamber 12 via a gas delivery injector 16. In one embodiment, argon is first flowed through the plasma generator 14 and process chamber 12 to ignite a plasma. Once a plasma is ignited, nitrogen is flowed through the plasma generator 14 and process chamber 12. In one embodiment, the nitrogen flow rate increases substantially linearly from 0 to about 5000 sccm over a time period of about 20 to 1800 seconds. During the nitridation process, process chamber 12 is maintained at a pressure in the range of about 1 to 100 Torr and at a wafer temperature in the range of 200 to 700. The wafer 13 having a dielectric film deposited thereon is placed in the process chamber 12 for a sufficient time for exposure to the nitrogen plasma. While the present invention is not limited to a particular theory, it is believed that reactive atomic nitrogen reacts with, for example, hafnium silicates deposited on the substrate to form hafnium silicate nitride. The reaction of atomic nitrogen with hafnium silicate is thermally-activated and results in the replacement of oxygen by nitrogen in the film. After the nitridation process is completed, the nitrogen plasma source 14 is turned off and the process chamber 12 is purged using purging gases.

The following examples are provided to illustrate the method of the present invention and are not intended to limit the scope of the invention.

### EXAMPLE 1

This example illustrates the method of the present invention that was performed in the reaction system 10 as shown in FIG. 1.

A wafer 13 having a 50 Å hafnium oxide (HfO₂) deposited thereon was placed in a loadlock chamber (not shown in FIG. 1). The loadlock chamber was cycle purged three times using an inert gas such as N₂ at a pressure in the range of about 100 Torr and atmospheric pressure to remove residual oxygen (O₂) and other reactant gases.

After the purge, the wafer 13 was loaded into the process chamber 12 which was maintained at a pressure of about 100 Torr. The wafer 13 was supported and clamped on the wafer chuck support 15. The wafer temperature was maintained in the range of about 300 to 600° C.

The chamber pressure was lowered to about 2 Torr. An argon gas was flowed through the plasma generator 14 and the process chamber 12 at a flow rate of approximately 10.8 slm. A plasma was ignited during the argon gas flow.

A nitrogen containing gas was then flowed through the plasma generator 14. The flow rate of the nitrogen containing gas was linearly increased from 0 to 1670 sccm over about 20 seconds. The argon and nitrogen plasma gases were introduced above the wafer 13 by an injector 16. Any type of injectors can be used such as but not limited to linear injectors and showerhead injectors. In this embodiment, a linear type of injector was used, such as that described in U.S. Pat. No. 6,521,048, the disclosure of which is hereby incorporated by reference. The pressure in the process chamber 12 was maintained at about 5 Torr during the flow of argon and nitrogen plasma gases.

During the plasma nitridation, the wafer was translated between a process start position and a process end position for 20 times at a speed of about 13.1 mm/sec for a total of 600 seconds to expose the wafer to the nitrogen plasma

The plasma generator 14 was then turned off and the process chamber 12 was restored to a pressure of about 100 Torr using a nitrogen purge gas.

The following Table 1 summarizes the process conditions used in this example:

TABLE 1

| | | | | | | Number |
|---|---|---|---|---|---|---|
| | | | | Process | Translate | of |
| Temp | Pressure | Ar Flow | N₂ flow | Time | Time | Passes |
| 570° C. | 5 Torr | 10.8 slm | 1.67 | 600 Sec. | 13.1 | 20 |
| | | | slm | | mm/sec. | |

Table 2 shows that the nitrogen containing hafnium-based films (Hf—O-N) produced by nitridizing hafnium oxide according to this example have good electrical properties. The resulted films were measured with a mercury probe (contact area: 9.4×10⁻⁵ cm²). The sample film demonstrated a low Tox (17.4 Å) with low leakage current density (4.0×10⁻⁷ A/cm²). The results of this example were compared with argon plasma treated wafers and “chuck only” heated (thermally treated) wafers, which exhibited undesirable leakage current densities of two to three orders of magnitude higher.

TABLE 2

| Run No. | Conditions | Tox (Å) | Jg @ −1 V (amp/cm2) |
|---|---|---|---|
| 1 | As deposited | 31.8 | 2.2E−07 |
| 2 | N plasma treated | 17.4 | 4.0E−07 |
| 3 | As deposited | 31.5 | 2.4E−07 |
| 4 | Ar plasma treated | 15.5 | 1.0E−04 |
| 5 | As deposited | 31.9 | 2.6E−07 |
| 6 | Thermally treated | 14.7 | 2.8E−05 |

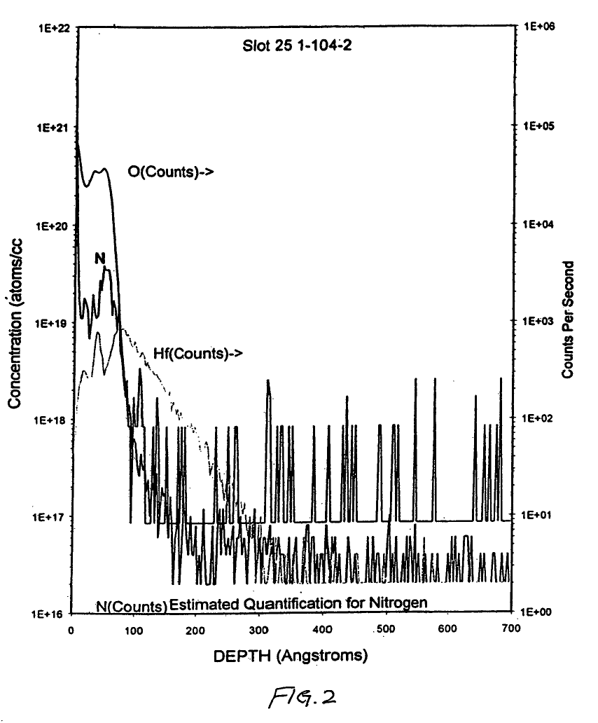

FIG. 2 is a SIMS plot showing the depth profile of a hafnium oxide film treated by nitrogen plasma according to one embodiment of the invention. The SIMS analysis demonstrated that nitrogen atoms were incorporated in the 50 Å HfO₂ film at a wafer temperature of 570° C.

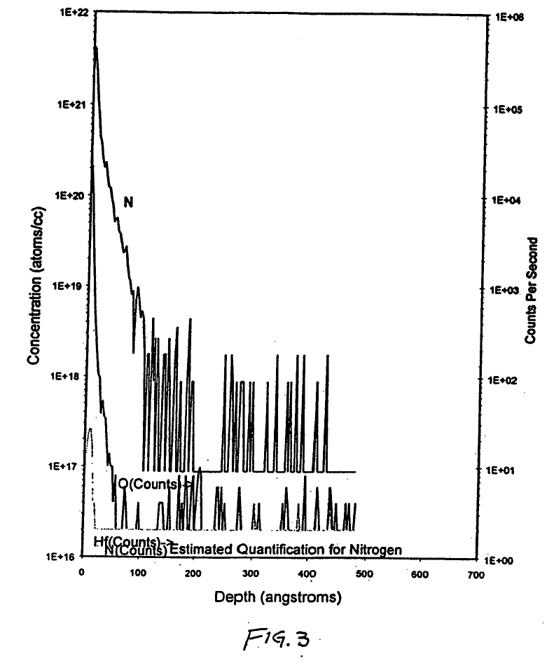

FIG. 3 is a SIMS plot showing the depth profile of a bare silicon wafer treated by nitrogen plasma according to one embodiment of the present invention. FIG. 3 clearly shows nitrogen incorporation in the top layer of the silicon substrate. The silicon substrate was etched using hydrogen fluoride (HF) within 30 minutes before the nitrogen plasma treatment.

FIGS. 2 and 3 demonstrate that nitrogen plasma can be used to incorporate nitrogen atoms in both hafnium oxide films and silicon substrates at a relatively low temperature to suppress formation of undesirable interfacial silicon oxides.

### EXAMPLE 2

This example illustrates the method of the present invention that was performed in an atomic layer deposition chamber for nitridation of hafnium silicates.

A wafer was first loaded in a loadlock chamber. The loadlock chamber was evacuated to vacuum before the wafer was transferred into an ALD chamber.

The wafer was transferred to a first ALD chamber to deposit a hafnium silicate film (HfₓSi₁₋ₓO₂, where x=0.2-0.9) on the wafer. A hafnium, and a silicon precursor were independently introduced into the ALD chamber to alternatively react with the surface of the wafer to form a hafnium silicate layer with a thickness of 50 Å.

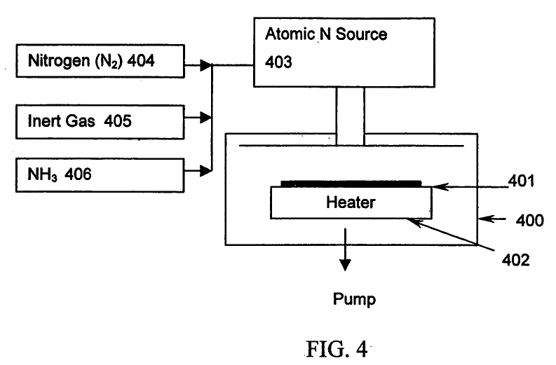

The wafer having 50 Å hafnium silicate deposited thereon was then transferred under vacuum to a second ALD chamber for nitridation of hafnium silicate. FIG. 4 is a schematic view of an ALD chamber 400 that was used in this example for nitridation of hafnium silicate. The wafer 401 was preheated on a susceptor 402 to a process temperature over a time period of about 30 to 300 seconds prior to the nitridation process. In one embodiment, the wafer was preheated for about 60 seconds.

A process gas was then introduced into a plasma generator 403 and to the region above the wafer through a tube having a diameter of 40 mm. The diameter of the tube should be sufficiently large to maintain a low pressure inside the remote plasma source. The process gas may include nitrogen from source 404, ammonia from source 406 and optionally an inert gas such as but not limited to Ar, He, or other inert gas from source 405. Alternatively, the process gas consists of only nitrogen-containing gases. In this specific example, the process gas contained argon and nitrogen. The Ar flow rate was about 0 to 300 sccm and N₂ flow rate was about 60 sccm to 2 slm. The gas pressure was about 90 mTorr to 1 Torr, which was maintained by gas flow, pumping speed, and throttle valve position.

A nitrogen plasma was introduced into the second ALD chamber 400 by turning on a plasma source 403. The time period for nitrogen plasma flow was about 5 to 30 minutes. The plasma source 403 used in this example was generated by a commercially available plasma generator.

At the end of the nitridation process, the plasma source 403 and process gas were turned off. The chamber 400 was evacuated to a base pressure (<1 mTorr) and the wafer 401 was transferred to the loadlock chamber (not shown in FIG. 4).

Table 3 summarizes the process conditions used in this example.

TABLE 3

| N₂ | Ar | Pressure | Temp | Power | Time |
|---|---|---|---|---|---|
| (sccm) | (sccm) | (mTorr) | (C.) | (kW) | (min) |
| 60 | 0 | 95 | 363 | | 30 |
| 1094 | 0 | 418 | 363 | | 30 |
| 60 | 300 | 233 | 363 | | 30 |
| 60 | 300 | 233 | 363 | | 30 |
| 1094 | 0 | 415 | 363 | | 30 |
| 1094 | 0 | 415 | 450 | | 30 |
| 1094 | 0 | 415 | 363 | | 30 |
| 1094 | 0 | 415 | 363 | 5.76 | 30 |
| 1094 | 0 | 1000 | 363 | 5.76 | 30 |
| 1094 | 0 | 415 | 363 | 2.76 | 30 |

Table 4 shows the levels of nitrogen incorporated into the HfSiO films formed by the method described in this example. The nitrogen measurements were completed by XPS.

TABLE 4

| N₂ | Ar | Pressure | Temp | Power | Time | N |
|---|---|---|---|---|---|---|
| (sccm) | (sccm) | (mTorr) | (C.) | (kW) | (min) | (Atomic %) |
| 60 | 300 | 233 | 363 | | 30 | <0.2 |
| 1094 | 0 | 415 | 363 | | 30 | 2.2 |
| 1094 | 0 | 415 | 450 | | 30 | 3.5 |
| 1094 | 0 | 415 | 363 | | 30 | 1.9 |
| 1094 | 0 | 415 | 363 | 5.76 | 30 | 2 |
| 1094 | 0 | 1000 | 363 | 5.76 | 30 | 0.5 |

The results demonstrate that significant levels of nitrogen can be incorporated into HfSiO₂ and that the level can be controlled based on process conditions.

### EXAMPLE 3

This example illustrates the method of the present invention that was performed in a hot-wall single wafer rapid thermal process chamber for nitridation of hafnium silicates.

A wafer was first coated with a HfSiO₂ film having a thickness of 50 Å. The HfSiO₂ film contained about 50% H_{f}.

The wafer with 50 Å HfSiO₂ was then loaded in a hot-wall single wafer rapid thermal process chamber for nitridation using a NH₃ containing gas. Table 5 summarizes the nitridation process conditions and the atomic percent of nitrogen incorporated into the HfSiO₂ film.

TABLE 5

| Temp (C.) | Time(Min) | Pressure (Torr) | N (%) |
|---|---|---|---|
| 700 | 0.5 | 5 | 0.9 |
| 700 | 5 | 5 | 4.4 |
| 700 | 5 | 50 | 5.5 |
| 800 | 5 | 50 | 18 |

FIG. 5 is a SIMS plot showing the depth profile of the HfSiOx film treated by the thermal nitridation. The results indicate that high levels of nitrogen can be incorporated into the HfSiOx films.

The foregoing description of specific embodiments and examples of the invention have been presented for the purpose of illustration and description, and although the invention has been illustrated by certain of the preceding examples, it is not to be construed as being limited thereby. They are not intended to be exhaustive or to limit the invention to the precise forms disclosed, and obviously many modifications, embodiments, and variations are possible in light of the above teaching. It is intended that the scope of the invention encompass the generic area as herein disclosed, and by the claims appended hereto and their equivalents.

What is claimed:

1. A method of forming a high-k dielectric film, comprising the steps of:
providing a substrate having a high-k dielectric film deposited thereon in a process chamber; and
introducing a nitrogen containing gas into the process chamber to incorporate nitrogen into the high-k dielectric film.

2. The method of claim 1 wherein the nitrogen containing gas comprises nitrogen (N₂), ammonia (NH₃), and mixtures thereof.

3. The method of claim 2 wherein the nitrogen containing gas further comprises an inert gas.

4. The method of claim 3 wherein the inert gas comprises Ar, He, N₂, and any mixtures thereof.

5. The method of claim 1 wherein the nitrogen containing gas comprises a nitrogen plasma.

6. The method of claim 5 wherein the nitrogen plasma is introduced from a source outside the process chamber.

7. The method of claim 1 wherein the nitrogen containing gas is introduced into the process chamber substantially linearly from 0 to 5000 sccm over a time period of about 20 to 1800 seconds.

8. The method of claim 1 wherein the process chamber is maintained at a pressure in the range of about 1 to 100 Torr, and at a temperature in the range of about 200 to 700° C.

9. The method of claim 8 wherein the process chamber is maintained at a temperature in the range of about 0.300 to 600° C.

10. The method of claim 1 wherein the high-k dielectric film comprises metal oxides or metal silicates.

11. The method of claim 10 wherein the metal oxides comprise hafnium oxides, and the metal silicates comprise hafnium silicates.

12. The method of claim 1 wherein the high-k dielectric film is deposited by atomic layer deposition, chemical vapor deposition (CVD), physical vapor deposition (PVD), jet vapor deposition (JVD), aerosol pyrolysis, or spin-coating.

13. The method of claim 1 which is performed in an atomic vapor deposition chamber.

14. The method of claim 1 which is performed in a rapid thermal process chamber.

15. The method of claim 14 which is performed in a hot-wall single wafer rapid thermal process chamber.

16. A method of forming a high-k dielectric film, comprising the steps of:
providing a substrate having a high-k dielectric film deposited thereon in a process chamber; and
introducing a nitrogen plasma gas into the process chamber to incorporate nitrogen into the high-k dielectric film.

17. The method of claim 16 wherein the nitrogen plasma gas is introduced from a source outside the process chamber.

18. The method of claim 16 wherein the nitrogen plasma gas is introduced into the process chamber substantially linearly from 0 to 5000 sccm over a time period of about 20 to 1800 seconds.

19. The method of claim 16 which is performed in an atomic layer deposition chamber.

20. The method of claim 16 wherein the process chamber is maintained at a pressure in the range of about 1 to 100 Torr and a temperature in the range of about 300 to 600° C.

21. The method of claim 16 wherein the high-k dielectric comprises metal oxides and metal silicates.

22. A method of forming a high-k dielectric film, comprising the steps of:
providing a substrate having a high-k dielectric film deposited thereon in a rapid thermal process chamber; and
introducing a nitrogen containing gas into the process chamber to incorporate nitrogen into the high-k dielectric film.

23. A method of forming a high-k dielectric film, comprising the steps of:
providing a substrate in a first process chamber;
forming a high-k dielectric film on the substrate by atomic layer deposition comprising alternatively reacting the surface of the substrate with a first and a second gas in the first process chamber;
transferring the substrate having the high-k dielectric film deposited thereon into a second process chamber; and
introducing a nitrogen plasma gas into the second process chamber to incorporate nitrogen into the high-k dielectric film.

24. The method of claim 23 wherein the high-k dielectric film deposited by atomic layer deposition comprises metal oxides or metal silicates.

25. The method of claim 23 wherein the nitrogen plasma gas is introduced from a source outside the second process chamber.

26. The method of claim 23 wherein the nitrogen plasma gas is introduced into the second process chamber substantially linearly from 0 to 5000 sccm over a time period of about 20 to 1800 seconds.

27. A method of forming a high-k dielectric film, comprising the steps of:
providing a substrate having a hafnium containing high-k dielectric film deposited thereon in a process chamber; and
introducing a nitrogen containing gas into the process chamber to incorporate nitrogen into the hafnium containing high-k dielectric film.

28. The method of claim 27 wherein the hafnium containing high-k dielectric film comprises hafnium oxides.

29. The method of claim 27 wherein the hafnium containing high-k dielectric film comprises hafnium silicates.

30. The method of claim 27 wherein the nitrogen containing gas comprises nitrogen (N₂), ammonia (NH₃), and mixtures thereof.

31. The method of claim 27 wherein the nitrogen containing gas comprises a nitrogen plasma.

32. The method of claim 27 wherein the process chamber is maintained at a pressure in the range of about 1 to 100 Torr, and at a temperature in the range of about 200 to 700° C.

33. The method of claim 27 which is performed in a rapid thermal process chamber maintained at a temperature in the range of 600-800° C. and a pressure in the range of 1-100 Torr.
